(19) United States
(12) Patent Application Publication
(10) Pub. No.: US 2026/0020305 A1
(43) Pub. Date: Jan. 15, 2026

(54) Stress Control of Thinned Epitaxial Silicon Devices and MEMS Structures

(71) Applicant: KLA Corporation, Milpitas, CA (US)

(72) Inventors: David Lee BROWN, Los Gatos, CA (US); Jehn-Huar Howard CHERN, Morgan Hill, CA (US)

(21) Appl. No.: 19/264,699

(22) Filed: Jul. 9, 2025

Related U.S. Application Data
(60) Provisional application No. 63/669,231, filed on Jul. 10, 2024.

(51) Int. Cl. H10D 62/834; H01L 21/02

(52) U.S. Cl. CPC H10D 62/834; H01L 21/02579

(57) ABSTRACT

A workpiece includes a doped p-type substrate, a co-doped P+ epitaxial silicon layer disposed on the doped p-type substrate, and a boron-doped P− epitaxial layer disposed on the co-doped P+ epitaxial silicon layer. The co-doped P+ epitaxial silicon layer is co-doped with germanium and boron. A ratio of the germanium to the boron in the co-doped P+ epitaxial silicon layer may be from 10 to 16.

### CROSS-REFERENCE TO RELATED APPLICATIONS

This application claims priority to the provisional patent application filed Jul. 10, 2025 and assigned U.S. App. No. 63/669,231, the disclosure of which is hereby incorporated by reference.

### FIELD OF THE DISCLOSURE

This disclosure relates to fabricating workpieces used in the semiconductor industry.

### BACKGROUND OF THE DISCLOSURE

A thin epitaxial silicon layer is often grown on a base silicon substrate. In a MEMS process, the substrate is mechanically thinned and etched with a pattern that defines a device geometry. The epitaxial layer may have different dopants or doping levels than the silicon substrate material. The epitaxial layer also may be of a higher quality than the silicon substrate material.

A relatively highly-doped P+ substrate may be needed for MEMS processing, such as to enable HNA etching (i.e., using a mixture of hydrofluoric, nitric, and acetic acid). When a low-doped epitaxial layer is part of the device fabrication, the workpiece may warp due to a lattice mismatch between the highly-doped P+ substrate and a later-formed epitaxial layer. This is caused by the reduced lattice constant from the heavy boron doping. The bow will negatively impact the ability to pattern the workpiece and to assemble the curved devices onto flat packages. The limitation may become severe for larger devices, including wafer-scale devices and for flip-chip type assembly processes. Improved workpieces and fabrication methods are needed.

### BRIEF SUMMARY OF THE DISCLOSURE

A workpiece is provided in a first embodiment. The workpiece includes a doped p-type substrate, a co-doped P+ epitaxial silicon layer disposed on the doped p-type substrate, and a boron-doped P− epitaxial layer disposed on the co-doped P+ epitaxial silicon layer. The co-doped P+ epitaxial silicon layer is co-doped with germanium and boron.

The co-doped P+ epitaxial silicon layer may have an induced warp prior to growth of the boron-doped P− epitaxial layer.

The workpiece may further include a dielectric film stack disposed on the boron-doped P− epitaxial layer. The dielectric film stack may include silicon oxide, silicon nitride, and/or polysilicon.

A ratio of the germanium to the boron in the co-doped P+ epitaxial silicon layer may be from 8 to 16.

The doped p-type substrate may have a doping concentration of 10¹² cm⁻³ to 10¹⁶ cm⁻³.

The doped p-type substrate may be doped with boron.

The boron-doped P− epitaxial layer may have a boron doping concentration of 10¹¹ cm⁻³ to 10¹³ cm⁻³.

A method to fabricate a workpiece is provided in a second embodiment. The method includes forming a co-doped P+ epitaxial silicon layer disposed on a doped p-type substrate using epitaxial growth. The co-doped P+ epitaxial silicon layer is co-doped with germanium and boron. A boron-doped P− epitaxial layer disposed on the co-doped P+ epitaxial silicon layer is formed using epitaxial growth.

The co-doped P+ epitaxial silicon layer may have an induced warp prior to growth of the boron-doped P− epitaxial layer.

The method may further include forming a dielectric film stack disposed on the boron-doped P− epitaxial layer. The dielectric film stack may include silicon oxide, silicon nitride, and/or polysilicon.

A ratio of the germanium to the boron in the co-doped P+ epitaxial silicon layer may be from 8 to 16.

The doped p-type substrate may have a doping concentration of 10¹² cm⁻³ to 10¹⁶ cm⁻³.

The doped p-type substrate may be doped with boron.

The boron-doped P− epitaxial layer may have a boron doping concentration of 10¹¹ cm⁻³ to 10¹³ cm⁻³.

The method may include thinning the doped p-type substrate via mechanical thinning and/or etching.

In an embodiment, the co-doped P+ epitaxial silicon layer is formed by at least partly simultaneous doping with the germanium and the boron.

### DESCRIPTION OF THE DRAWINGS

For a fuller understanding of the nature and objects of the disclosure, reference should be made to the following detailed description taken in conjunction with the accompanying drawings, in which:

FIGS. 1A-1E show a first workpiece manufacturing embodiment in accordance with the present disclosure; and

FIGS. 2A-2E show a second workpiece manufacturing embodiment in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Workpieces for MEMS applications may be thinned during manufacturing. The thinning process requirements may restrict the doping of layers in the workpiece. An etchant chemistry may only be effective if certain dopants or doping levels are used. Embodiments disclosed herein can enable widely-available substrates to be used with a MEMS process that requires high p-type doping while providing lower stress and reduced wafer warping. This reduces the defect density in the workpiece material and allows for thinned devices to be packaged more easily for higher yield. For example, SiGe workpieces can be produced. The workpieces disclosed herein can be used for sensors, which can be sensitive to defects.

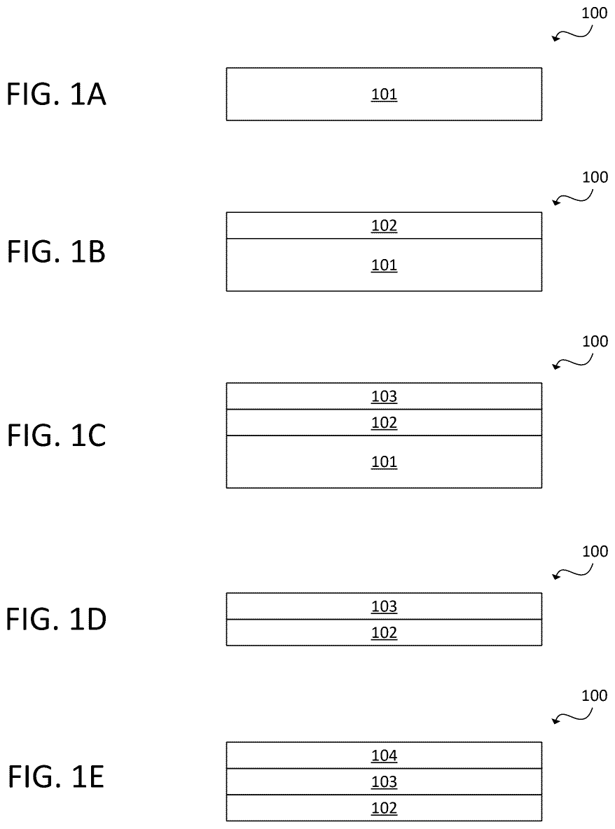

FIGS. 1A-1E show a first workpiece manufacturing embodiment. The presence of boron in silicon will cause a lattice mismatch with other silicon layers. An additional layer of P+ doped epitaxial silicon is grown on the doped p-type substrate. The epitaxial P+ doped layer is co-doped with, for example, germanium and boron to achieve the lattice constant close to or matching both the undoped Si and the doped p-type substrate. This results in low stress and minimal warping of the workpiece.

FIG. 1A shows part of the workpiece 100. The workpiece includes a doped p-type substrate 101. The doped p-type substrate 101 may have a thickness from 300 μm to 1000 μm. For example, the substrate may have a thickness of 675 μm, 725 μm, or 775 μm. The doped p-type substrate 101 may be silicon. The doped p-type substrate 101 may serve as a carrier. The doped p-type substrate 101 may have relatively low p-type doping. For example, the doped p-type substrate 101 may have a doping concentration from 10¹² cm⁻³ to 10¹⁶ cm⁻³. The doped p-type substrate 101 may be doped with boron.

While described as p-type, a doped n-type substrate may be used as the carrier instead of the doped p-type substrate 101. Such a doped n-type substrate may be doped with arsenic or phosphorus. The lattice mismatch can be compensated for using germanium and boron co-doping as described herein.

At FIG. 1B, a co-doped P+ epitaxial silicon layer 102 is formed on the doped p-type substrate 101 using epitaxial growth. The co-doped P+ epitaxial silicon layer 102 may have a thickness from approximately 100 μm to 1000 μm. The co-doped P+ epitaxial silicon layer 102 can include silicon. The co-doped P+ epitaxial silicon layer may be co-doped with germanium and boron. A ratio of germanium to boron may depend on absolute concentrations and process conditions. A ratio of germanium to boron from approximately 8× to 16× may be used. Co-doping within this range can provide a lattice constant close to or matching undoped silicon or the 1 doped p-type substrate 101, though other ratios are possible. This results in low stress and minimal warping of the workpiece 100. Stress of 1 MPa or more can be induced in the co-doped P+ epitaxial silicon layer 102. Actual stress in the co-doped P+ epitaxial silicon layer 102 may depend on thicknesses and doping levels.

The co-doped P+ epitaxial silicon layer 102 has a lattice constant similar to the doped p-type substrate 101. Mismatches between the co-doped P+ epitaxial silicon layer 102 and the doped p-type substrate 101 may be negligible. For example, mismatches less than 1E-6 Angstroms for 1E14 cm⁻³ boron concentration may be possible. The SiGe layer will match the p-type doping in the doped p-type substrate 101. In an instance, the presence of germanium matches the p− doping in the doped p-type substrate 101. This reduces warping of the workpiece 100. In an embodiment, warping can be reduced to zero or even become negative. The doping levels, thicknesses, and other variables can be optimized to provide the desired level of warping compensation. Reduced bowing, lower strain or stress, and/or lower defect density in the workpiece 100 also can be achieved.

In an embodiment, a ratio of the germanium to the boron in the co-doped P+ epitaxial silicon layer is from 10× to 16× or from 11× to 16×. The co-doping with boron and germanium can occur at least partly or entirely simultaneously. Co-doping with boron and germanium may unexpectedly change this ratio compared to separately doping with boron and germanium. Germanium may be used because of how it resides in the silicon lattice. Germanium also may enable alkaline etches or acid etches because it will serve as a barrier.

At FIG. 1C, a boron-doped P− epitaxial layer 103 is formed on the co-doped P+ epitaxial silicon layer 102 using epitaxial growth. The boron-doped P− epitaxial layer 103 may have a thickness from approximately 5 μm to 200 μm. The boron-doped P− epitaxial layer 103 can include silicon. The boron-doped P− epitaxial layer 103 is formed on the co-doped P+ epitaxial silicon layer 102 opposite of the doped p-type substrate 101. Thus, the resulting workpiece 100 includes the doped p-type substrate 101, the co-doped P+ epitaxial silicon layer 102 disposed on the doped p-type substrate 101, and the boron-doped P− epitaxial layer 103 disposed on the co-doped P+ epitaxial silicon layer 102. The boron-doped P− epitaxial layer 103 may have a doping concentration from 10¹¹ cm⁻³ to 10¹³ cm⁻³. This doping level in the boron-doped P− epitaxial layer 103 is less than the doping level in the co-doped P+ epitaxial silicon layer 102. This doping level in the boron-doped P− epitaxial layer also may assist with reverse bias depletion. A sensor fabricated with the workpiece 100 may be electrically biased to operate. Heavy doping above this range may prevent deep depletion of a resulting sensor.

At FIG. 1D, the doped p-type substrate 101 is thinned from the workpiece 100. The doped p-type substrate 101 can be thinned using, for example, mechanical thinning (e.g., grinding) and/or etching (e.g., HNA etching). A mechanical thinning may provide a flat, uniform surface. Etching can be uniform or may be combined with a mask to etch specific shapes into the material at different locations. Some or all of the doped p-type substrate 101 may be removed. In an instance, all of the doped p-type substrate 101 is removed from the workpiece 100. Thinning may occur before device fabrication. After thinning, the co-doped P+ epitaxial silicon layer 102 can become the effective substrate for the boron-doped P− epitaxial layer 103.

The co-doped P+ epitaxial silicon layer 102 can enable etching. Acid etching may preferentially etch specific materials. Here, an acid etch can remove layers up to the P+ material. Undoped or low doped epitaxial layers, such as that in the co-doped P+ epitaxial silicon layer 102, has a slow etch rate and can serve as an etch stop at the interface with the doped p-type substrate 101.

The resulting workpiece in FIG. 1C or FIG. 1D may nearly flat or entirely flat. Minimal warp or bow is typically desired. A number of defects on the workpiece is likewise minimized.

At FIG. 1E, a dielectric film stack 104 is formed on the boron-doped P− epitaxial layer 103. The dielectric film stack 104 may include silicon oxide, silicon nitride, and/or polysilicon. The workpiece 100 may be used as a gate dielectric insulator for electronics applications in an embodiment. In another embodiment, the workpiece 100 may be used as a passivation layer for an optical interface.

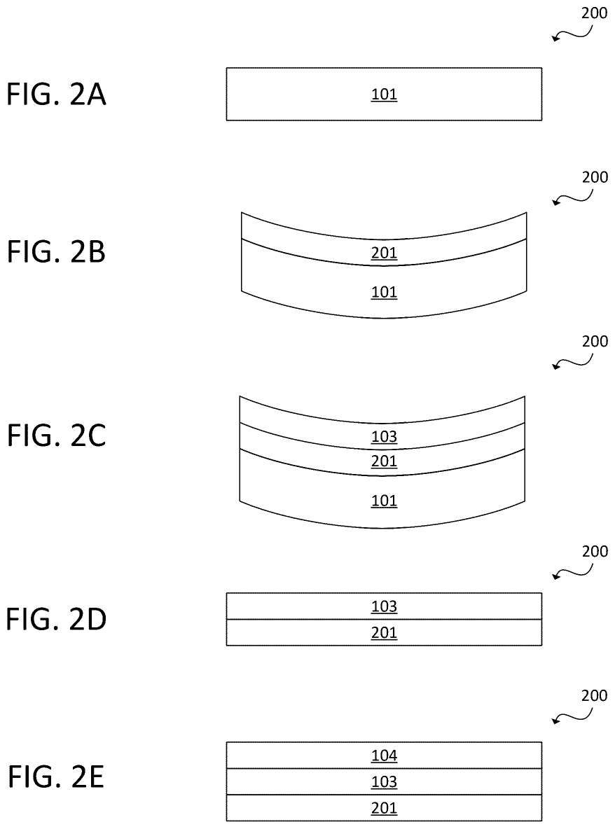

FIGS. 2A-2E show a second workpiece manufacturing embodiment. Features of the workpiece 200 may include like-numbered features of the workpiece 100. The workpiece 200 includes a co-doped P+ epitaxial silicon layer 201 with a ratio of germanium to boron from approximately 8× to 16×. This induces a warp in the co-doped P+ epitaxial silicon layer 201 and the doped p-type substrate 101. The warp can extend to the boron-doped P− epitaxial layer 103 that is grown on the co-doped P+ epitaxial silicon layer 201.

The workpiece 200 overcompensates to intentionally induce stress and warp during the initial steps of workpiece 200 fabrication. The induced stress compensates for the stress in the workpiece 200 after the co-doped P+ epitaxial silicon layer 201 is formed. The added stress may form some stress-induced defects, but also may achieve a lower final warp in the workpiece 200 after fabrication steps that introduce additional stress. Workpiece 200 warping from the dielectric film stack 104 also can be mitigated by inducing stress. The dielectric film stack 104 may cause a compressive stress, but the overcompensation can result in a flat workpiece 200. Film stress can be estimated, simulated, or inferred from a measured bow on an uncompensated workpiece 100.

Embodiments disclosed herein enable use of highly-doped materials with low resistivity and low warpage. Commercially-available silicon substrates may be used to create these workpieces. For example, lower-doped, commercially-available silicon substrates can be used and low-stress epitaxial silicon can be produced on the highly-doped material. Acid etching during MEMS processing can be performed. Removal of the substrate during processing can allow the remaining workpiece material to be used in MEMS processing, which may use p+ doped silicon. The germanium-doped material may not be directly incorporated into transistors or other active devices. Germanium can change the behavior of electrically-active silicon devices. The embodiments disclosed herein do not need to dope the silicon layer where devices are formed. The electrical properties can be unchanged except from any reduced defect density. Instead, the germanium-doped material can be used as a substrate or carrier for other layers. TDI sensors can be fabricated and assembled with a higher yield using the embodiments disclosed herein.

The various layers of the workpiece 100 and the workpiece 200 are illustrated as being directly disposed on each other without intervening layers. In other embodiments, additional layers are formed between the layers of the workpiece 100 and workpiece 200 that are illustrated herein.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A workpiece comprising:
a doped p-type substrate;
a co-doped P+ epitaxial silicon layer disposed on the doped p-type substrate, wherein the co-doped P+ epitaxial silicon layer is co-doped with germanium and boron; and
a boron-doped P− epitaxial layer disposed on the co-doped P+ epitaxial silicon layer.

2. The workpiece of claim 1, wherein the co-doped P+ epitaxial silicon layer has an induced warp prior to growth of the boron-doped P− epitaxial layer.

3. The workpiece of claim 1, further comprising a dielectric film stack disposed on the boron-doped P− epitaxial layer.

4. The workpiece of claim 3, wherein the dielectric film stack includes silicon oxide, silicon nitride, and/or polysilicon.

5. The workpiece of claim 1, wherein a ratio of the germanium to the boron in the co-doped P+ epitaxial silicon layer is from 8 to 16.

6. The workpiece of claim 1, wherein the doped p-type substrate has a doping concentration of 10¹² cm⁻³ to 10¹⁶ cm⁻³.

7. The workpiece of claim 1, wherein the doped p-type substrate is doped with boron.

8. The workpiece of claim 1, wherein the boron-doped P− epitaxial layer has a boron doping concentration of 10¹¹ cm⁻³ to 10¹³ cm⁻³.

9. A method to fabricate a workpiece comprising:
forming a co-doped P+ epitaxial silicon layer disposed on a doped p-type substrate using epitaxial growth, wherein the co-doped P+ epitaxial silicon layer is co-doped with germanium and boron; and
forming a boron-doped P− epitaxial layer disposed on the co-doped P+ epitaxial silicon layer using epitaxial growth.

10. The method of claim 9, wherein the co-doped P+ epitaxial silicon layer has an induced warp prior to growth of the boron-doped P− epitaxial layer.

11. The method of claim 9, further comprising forming a dielectric film stack disposed on the boron-doped P− epitaxial layer, wherein the dielectric film stack includes silicon oxide, silicon nitride, and/or polysilicon.

12. The method of claim 9, wherein a ratio of the germanium to the boron in the co-doped P+ epitaxial silicon layer is from 8 to 16.

13. The method of claim 9, wherein the doped p-type substrate has a doping concentration of 10¹² cm⁻³ to 10¹⁶ cm⁻³.

14. The method of claim 9, wherein the doped p-type substrate is doped with boron.

15. The method of claim 9, wherein the boron-doped P− epitaxial layer has a boron doping concentration of 10¹¹ cm⁻³ to 10¹³ cm⁻³.

16. The method of claim 9, further comprising thinning the doped p-type substrate via mechanical thinning and/or etching.

17. The method of claim 9, wherein the co-doped P+ epitaxial silicon layer is formed by at least partly simultaneous doping with the germanium and the boron.
